(19) United States
(12) Patent Application Publication
(10) Pub. No.: US 2024/0198479 A1
(43) Pub. Date: Jun. 20, 2024

(54) POLISHING HEAD, POLISHING DEVICE AND METHOD OF MANUFACTURING SEMICONDUCTOR WAFER

(71) Applicant: SUMCO CORPORATION, Tokyo (JP)

(72) Inventors: Hiroki OTA, Saga (JP); Ryoya TERAKAWA, Saga (JP)

(73) Assignee: SUMCO CORPORATION, Tokyo (JP)

(21) Appl. No.: 18/545,306

(22) Filed: Dec. 19, 2023

(30) Foreign Application Priority Data
Dec. 20, 2022 (JP) 2022-203230

(51) Int. Cl. B24B 37/30; B24B 37/04

(52) U.S. Cl. CPC B24B 37/30; B24B 37/04

(57) ABSTRACT

The polishing head has, with the direction toward the center of the opening of the first annular member assumed as the inside, and with the other direction assumed as the outside, the space, formed by closing the opening of the first annular member by the closing member and the membrane, and partitioned into an inside space and an outside space by an annular partition wall with a top annular connection part connected to the closing member and with a bottom annular connection part connected to the membrane, the inside diameter of the bottom annular connection part of the annular partition wall is larger than the inside diameter of the second annular member, and the radius of the top annular connection part of the annular partition wall is 33% or more and 90% or less with the radius of the setting position of the work to be polished assumed as 100%.

### CROSS REFERENCE TO RELATED APPLICATIONS

This application claims priority under 35 U.S.C 119 to Japanese Patent Application No. 2022-203230 filed on Dec. 20, 2022, which is expressly incorporated by reference in its entirety.

### TECHNICAL FIELD

The present invention relates to a polishing head, a polishing device and a method of manufacturing a semiconductor wafer.

### BACKGROUND ART

The devices for polishing the surface of a work such as a semiconductor wafer include a one-side polishing device for polishing one side of a work, and a both-side polishing device for polishing both sides of a work. With the one-side polishing device, normally, while pressing the surface to be polished of a work held by a polishing head against a polishing pad bonded to a surface plate, the polishing head and the surface plate are rotated, respectively, thereby bringing the surface to be polished of the work and the polishing pad into sliding contact with each other. By supplying an abrasive to between the surface to be polished and the polishing pad thus coming in sliding contact with each other, it is possible to polish the surface to be polished of the work.

As the method for pressing the work held by the polishing head against the polishing pad in the one-side polishing device as described above, a rubber chuck system is known (see Japanese Patent No. 4833355, which is expressly incorporated by reference in its entirety).

### SUMMARY OF INVENTION

With the polishing head of the rubber chuck system, by introducing a gas such as air into the space at the back surface of a membrane (which is referred to as a rubber film in Japanese Patent No. 4833355), and thereby swelling the membrane, it is possible to press the work.

Japanese Patent No. 4833355 discloses a polishing head with the space partitioned into two spaces (see FIG. 1 and the like of Japanese Patent No. 483335). Below, the polishing head with the space at the back surface of the membrane partitioned into two spaces will be referred to as a two-zone membrane head. The present inventors studied the two-zone membrane head, and proved that in-plane fluctuations in polishing amount tends to be caused at the surface to be polished of the work.

One aspect of the present invention provides for a two-zone membrane head capable of enhancing the in-plane uniformity of the polishing amount at the surface to be polished of the work.

One aspect of the present invention is as follows.

[1] A polishing head having:
a first annular member,
a closing member which closes the upper surface side opening of the opening of the first annular member,
a membrane which closes the lower surface side opening of the opening of the first annular member, and
a second annular member situated under the membrane, and having an opening which holds a work to be polished, in which
with the direction toward the center of the opening of the first annular member assumed as the inside, and with the other direction assumed as the outside,
the space, which is formed by closing the opening of the first annular member by the closing member and the membrane, is partitioned into an inside space and an outside space by an annular partition wall with a top annular connection part connected to the closing member and with a bottom annular connection part connected to the membrane,
the inside diameter of the bottom annular connection part of the annular partition wall is larger than the inside diameter of the second annular member, and
the radius of the top annular connection part of the annular partition wall is 33% or more and 90% or less with the radius of the setting position of the work to be polished assumed as 100%.

[2] The polishing head according to [1], in which the shape of the surface to be polished of the work to be polished is a concave shape.

[3] The polishing head according to [1] or [2], in which
the annular partition wall includes a side surface shape selected from the group consisting of an inclined shape and a horizontal shape in a cross-sectional shape, and
vertically under at least a part of the side surface shape, a region including the inside circumferential end of the second annular member and the outside circumferential end of the setting position of the work to be polished is situated.

[4] The polishing head according to any of [1] to [3], in which
the closing member includes a top disk-shaped member and a bottom disk-shaped member having a smaller outside diameter than that of the top disk-shaped member, and
in the annular partition wall, the top annular connection part is connected with the side surface of the bottom disk-shaped member.

[5] The polishing head according to any of [1] to [4], further having a back pad between the membrane and the second annular member.

[6] The polishing head according to any of [1] to [5], further having:
an introduction path which introduces a gas into the inside space; and
an introduction path which introduces a gas into the outside space.

[7] The polishing head according to [1], in which
the shape of the surface to be polished of the work to be polished is a concave shape,
the annular partition wall includes a side surface shape selected from the group consisting of an inclined shape and a horizontal shape in a cross-sectional shape,
vertically under at least a part of the side surface shape, a region including the inside circumferential end of the second annular member and the outside circumferential end of the setting position of the work to be polished is situated,
the closing member includes a top disk-shaped member and a bottom disk-shaped member having a smaller outside diameter than that of the top disk-shaped member, and
in the annular partition wall, the top annular connection part is connected with the side surface of the bottom disk-shaped member,
the polishing head further has a back pad between the membrane and the second annular member, and
the polishing head further has;
an introduction path which introduces a gas into the inside space, and
an introduction path which introduces a gas into the outside space.

[8] A polishing device, having:
the polishing head according to any of [1] to [7];
a polishing pad; and
a surface plate which supports the polishing pad.

[9] A method of manufacturing a semiconductor wafer, including polishing the surface of the semiconductor wafer to be polished by the polishing device according to [8] to form a polished surface.

The polishing head (two-zone membrane head) in accordance with one aspect of the present invention can enhance the in-plane uniformity of the polishing amount at the surface to be polished of the work.

### BRIEF DESCRIPTION OF DRAWINGS

FIG. 1 is a schematic cross-sectional view showing one example of a polishing head in accordance with one aspect of the present invention.

FIG. 2 is an explanatory view of a connection part of an annular partition wall 15A in a polishing head 1A shown in FIG. 1.

FIG. 3 is an explanatory view of a connection part of the annular partition wall 15A in the polishing head 1A shown in FIG. 1.

FIG. 4 is an explanatory view of the inner wall surface of the annular partition wall and the upper surface of a membrane.

FIG. 5 is a schematic cross-sectional view showing one example of a polishing head in accordance with one aspect of the present invention.

FIG. 6 is a schematic cross-sectional view showing one example of the polishing head in accordance with one aspect of the present invention.

FIG. 7 is a schematic cross-sectional view showing one example of the polishing head in accordance with one aspect of the present invention.

FIG. 8 is a schematic cross-sectional view showing one example of a polishing device in accordance with one aspect of the present invention.

FIG. 9 is a graph plotting the GBIR values before and after the polishing treatment for the silicon wafer subjected to a polishing treatment 1 using each polishing head of Example and Comparative Example.

FIG. 10 is a graph plotting the GBIR values before and after the polishing treatment for the silicon wafer subjected to a polishing treatment 2 using each polishing head of Example and Comparative Example.

### DESCRIPTION OF EMBODIMENTS

### [Polishing Head]

A polishing head in accordance with one aspect of the present invention has a first annular member, a closing member which closes the upper surface side opening of the opening of the first annular member, a membrane which closes the lower surface side opening of the opening of the first annular member, and a second annular member situated under the membrane, and having an opening which holds a work to be polished. In the above polishing head, with the direction toward the center of the opening of the first annular member assumed as the inside, and with the other direction assumed as the outside, the space, which is formed by closing the opening of the first annular member by the closing member and the membrane, is partitioned into an inside space and an outside space by an annular partition wall with a top annular connection part connected to the closing member and with a bottom annular connection part connected to the membrane, the inside diameter of the bottom annular connection part of the annular partition wall is larger than the inside diameter of the second annular member, and the radius of the top annular connection part of the annular partition wall is 33% or more and 90% or less with the radius of the setting position of the work to be polished assumed as 100%.

Below, the polishing head will be further described in details. In the present invention and in the present specification, the expressions of “lower surface”, “under”, “upper surface”, “top”, “bottom”, and the like mean “lower surface”, “under”, “upper surface”, “top”, “bottom”, and the like when the polishing head is placed in a state in which a polishing process is performed. In the present invention and in the present specification, for the expressions “inclined” and “horizontal”, the case where the polishing head is inclined with respect to the horizontal direction when the polishing head is placed in a state in which a polishing process is performed is referred to as “inclined”, and the case where the polishing head is in parallel with such a horizontal direction is referred to as “horizontal”. Further, the direction toward the center of the opening of the first annular member is referred to as inside, and the other direction is referred to as outside. The term “annular” means the shape having an opening, and the shape of the opening in a plan view can be a circular shape. Below, the present invention will be described by way of the accompanying drawings. However, the embodiments shown in the drawings are illustrative, and the present invention is not limited to such embodiments. Further, the same portions are given the same reference numerals and signs in the drawings.

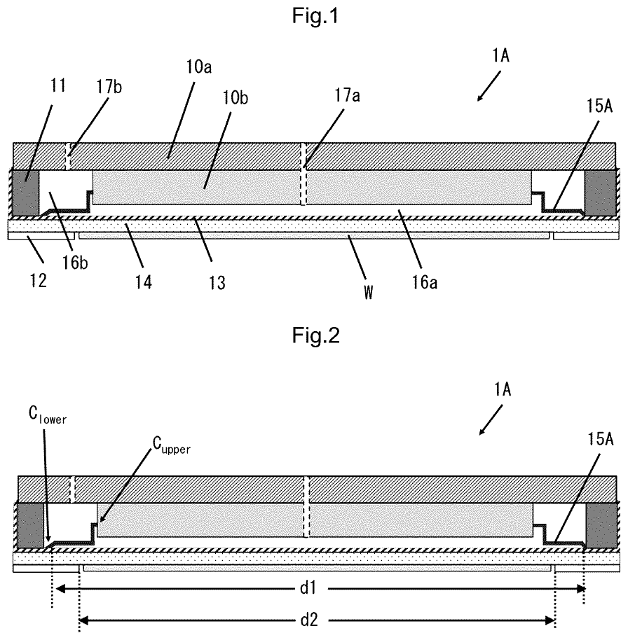

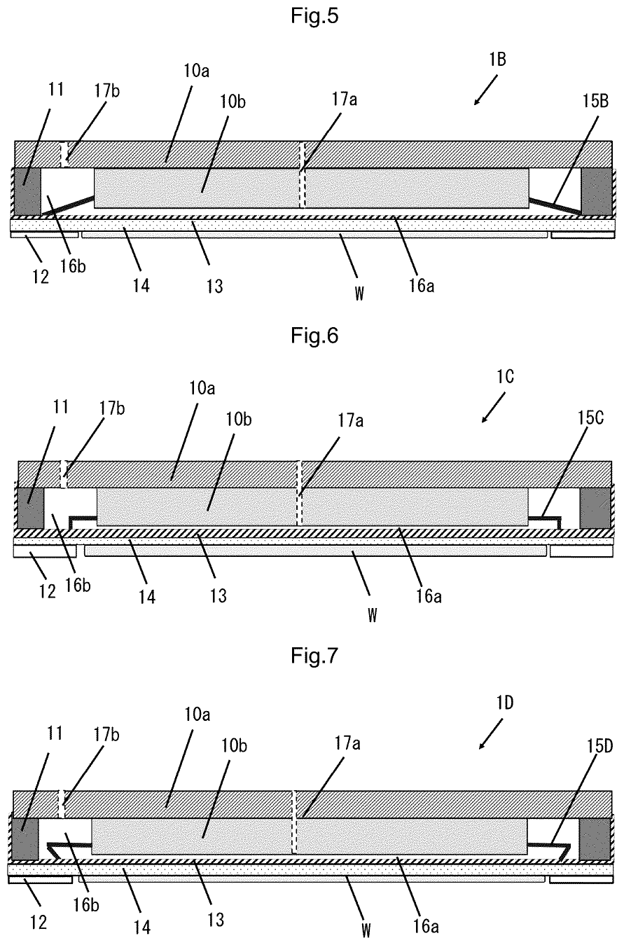

FIGS. 1, and 5 to 7 are each a schematic cross-sectional view showing one example of the polishing head in accordance with one aspect of the present invention. A polishing head 1A in FIG. 1, a polishing head 1B in FIG. 5, a polishing head 1C in FIG. 6, and a polishing head 1D in FIG. 7 may be collectively referred to as a polishing head 1. Further, an annular partition wall 15A in FIG. 1, an annular partition wall 15B in FIG. 5, an annular partition wall 15C in FIG. 6, and an annular partition wall 15D in FIG. 7 may be collectively referred to as an annular partition wall 15. In each drawing of FIGS. 1, and 5 to 7, the head main body is not shown. Above the portion shown in each drawing of FIGS. 1, and 5 to 7, a head main body is situated, and the portion shown in each drawing is mounted on the head main body by a known method such as fastening by a bolt.

In each drawing of FIGS. 1, and 5 to 7, the polishing head 1 has a first annular member 11. The first annular member 11 has an annular upper surface and an annular lower surface. The inside diameter of the upper surface is the same value as that of the inside diameter of the lower surface, and the outside diameter of the upper surface is the same value as that of the outside diameter of the lower surface. That is, the first annular member 11 has a cylindrical outside shape, and the shape of the opening is also a cylindrical shape. This also applies to a second annular member 12 described later. In the present invention and in the present specification, the term “the same value” is used as the meaning including the case of perfect match, and the case including an error that can be caused inevitably in manufacturing. This also applies to the term regarding the shape such as a cylindrical shape. As the first annular member 11, there can be used an annular ring made of a rigid material such as stainless steel material (SUS) to be normally used for the polishing head of a one-side polishing device.

The lower surface of the first annular member 11 is covered with a membrane 13. The membrane 13 may close at least the lower surface side opening of the first annular member 11. From the viewpoint of suppressing the occurrence of misalignment when the membrane 13 is swollen, and the viewpoint of suppressing mixing of an abrasive into the opening of the first annular member 11, the entire annular lower surface of the first annular member 11 is also preferably covered with the membrane 13. The membrane 13 can be bonded with the annular lower surface of the first annular member 11 by a known method such as use of an adhesive. Further, as shown in each drawing of FIGS. 1, and 5 to 7, the membrane 13 is also preferably bonded so as to extend over a part of, or the whole of the side surface of the first annular member 11. As the membrane 13, a film made of a material having elasticity such as rubber can be used. Examples of the rubber may include fluoro-rubber. The thickness of the membrane 13 has no particular restriction, and can be, for example, about 0.5 to 2 mm.

In each drawing of FIGS. 1, and 5 to 7, the lower surface of the membrane 13 is bonded with a back pad 14. The back pad 14 can be bonded with the lower surface of the membrane 13 by a known method such as use of an adhesive. The outer circumferential region of the lower surface of the membrane 13 and the annular upper surface of the second annular member 12 can come in direct contact with each other. However, from the viewpoint of suppressing peeling of the membrane 13 and the occurrence of undulation, the back pad 14 is preferably interposed between the outer circumferential region of the lower surface of the membrane 13 and the annular upper surface of the second annular member 12. As the back pad 14, for example, a disk-shaped sheet made of a material showing an adsorptive property due to the surface tension of water upon containing water (for example, foamed polyurethane) can be used. As a result of this, the back pad 14 containing water upon polishing can be allowed to hold a work.

In each of FIGS. 1, and 5 to 7, the membrane 13 closes the lower surface side opening of the first annular member 11. The upper surface side opening of the first annular member 11 is closed with a closing member formed of a top disk-shaped member 10a and a bottom disk-shaped member 10b. The bottom disk-shaped member 10b is a disk-shaped member with a smaller outside diameter than that of the top disk-shaped member 10a. The top disk-shaped member 10a and the bottom disk-shaped member 10b can be each a disk-shaped flat sheet with the upper surface outside diameter and the lower surface outside diameter being the same value, and can be arranged, for example, coaxially. In each drawing of FIGS. 1, and 5 to 7, the top disk-shaped member 10a and the bottom disk-shaped member 10b are different members, and are each fixed by any means (for example, a method in which a concave part is provided in one member, and a convex part is provided in the other member, so that the convex part is fitted in the concave part, fastening with a bolt, or bonding with an adhesive). However, the polishing head in accordance with one aspect of the present invention is not limited to such a configuration. The closing member can be a member including a top disk-shaped part and a bottom disk-shaped part with a smaller outside diameter than that of the top disk-shaped part formed integrally with each other therein. The material forming the closing member has no particular restriction. In each drawing of FIGS. 1, and 5 to 7, W shows the setting position of a work. At the time of polishing a work, when a gas is introduced into the space surrounded by the first annular member 11, the membrane 13, and the closing member, the membrane 13 is swollen. As a result of this, the work set at the work setting position W is pressed via the back pad 14, so that polishing is performed.

In each drawing of FIGS. 1, and 5 to 7, the space surrounded by the first annular member 11, the membrane 13, and the closing member is partitioned into an inside space 16a and an outside space 16b with the annular partition wall 15. The annular partition wall 15 can be manufactured by, for example, forming a material having elasticity such as rubber into a desirable shape. Examples of rubber may include fluoro-rubber. The thickness of the annular partition wall 15 can be set at, for example, about 0.5 to 1.5 mm. A gas can be introduced into the inside space 16a through a gas introduction path 17a penetrating through the top disk-shaped member 10a and the bottom disk-shaped member 10b at the central part of the closing member, and into the outside space 16b through a gas introduction path 17b penetrating through the top disk-shaped member 10a in the outer circumferential region of the closing member by controlling the gas introduction amounts each independently. At the time of polishing a work, for example, by varying the amount of the gas to be introduced into the inside space 16a through the gas introduction path 17a and the amount of the gas to be introduced into the outside space 16b through the gas introduction path 17b, it is possible to control the polished surface pressure to be applied to the outer circumferential region of the surface to be polished of the work under the outside space 16b independently of the polished surface pressure to be applied to the central part of the surface to be polished of the work under the inside space 16a. In each drawing of FIGS. 1, and 5 to 7, there are one gas introduction path 17a and one gas introduction path 17b. However, the present invention is not limited to such an embodiment, and two or more gas introduction paths 17a can be provided, and two or more gas introduction paths 17b can be provided.

In each drawing of FIGS. 1, and 5 to 7, a second annular member 12 is arranged under the membrane 13 via the back pad 14. The second annular member 12 is an annular member having an opening which holds a work to be polished. Such an annular member is generally also referred to as a retainer, a retainer ring, a template, or the like. The second annular member 12 can be an annular member made of a material to be commonly used for an annular member referred to as a retainer of a polishing head, or the like (for example, made of glass epoxy).

FIG. 2 is an explanatory view of the connection part (particularly, the bottom annular connection part) of the annular partition wall 15A in the polishing head 1A shown in FIG. 1. The annular partition wall 15A is configured such that the top annular connection part Cᵤₚₚₑᵣ is connected with the closing member, and such that the bottom annular connection part C_{lower} is connected with the membrane 13. Particularly, the top annular connection part Cᵤₚₚₑᵣ is connected with the side surface of the bottom disk-shaped member 10b of the closing member, and the bottom annular connection part C_{lower} is connected with the upper surface of the membrane 13. As respective connecting means of connection, mention may be made of a known method such as use of an adhesive, integral forming, or fitting of the convex part into the concave part. With the polishing head in accordance with one aspect of the present invention, the inside diameter d1 of the bottom annular connection part of the annular partition wall is larger than the inside diameter d2 of the second annular member, where d1 represents the inside diameter of the bottom annular connection part of the annular partition wall, and d2 represents the inside diameter of the second annular member. That is, the relationship of “d1>d2” is satisfied. Therefore, for polishing a work, vertically under the bottom annular connection part of the annular partition wall, the second annular member is situated, and the outer circumferential region of the surface to be polished of the work is not situated. In the work polished using the polishing head for which the outer circumferential region of the surface to be polished of the work is situated vertically under the connection part of the partition, local fluctuations in polishing amount (specifically, the local reduction of the polishing amount vertically under the connection part) tend to be caused. In contrast, with the polishing head in accordance with one aspect of the present invention, satisfaction of the relationship of “d1>d2” enables polishing of the surface to be polished of the work by suppressing the local reduction of the polishing amount vertically under the connection part. This is considered by the present inventors. With d2 assumed as 100%, d1 is more than 100%, preferably more than 102%, and more preferably 103% or more. With d2 assumed as 100%, d1 can be, for example, 120% or less, or 110% or less, or can exceed the values herein exemplified.

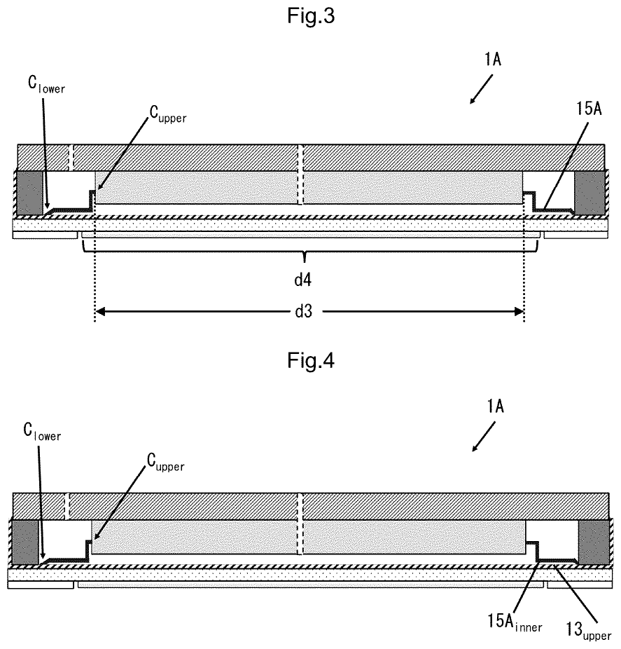

FIG. 3 is an explanatory view of the connection part (particularly, the top annular connection part) of the annular partition wall 15A in the polishing head 1A shown in FIG. 1. The annular partition wall 15A is configured such that the top annular connection part Cᵤₚₚₑᵣ is connected with the side surface of the bottom disk-shaped member 10b of the closing member. In FIG. 3, two dotted lines are straight lines drawn toward vertically under the top annular connection part Cᵤₚₚₑᵣ. As indicated with the two dotted lines, the outer circumferential region of the setting position W of the work to be polished is situated vertically under the top annular connection part Cᵤₚₚₑᵣ. Herein, the term “outer circumferential region” is assumed to represent a partial region from the outside circumferential end toward the radial inside. In each drawing of FIGS. 1 and 5 to 7, the top annular connection part Cᵤₚₚₑᵣ of the annular partition wall 15 is connected with the respective side surface of the bottom disk-shaped member 10b of the closing member. For this reason, vertically under the top annular connection part Cᵤₚₚₑᵣ is also vertically under the side surface of the bottom disk-shaped member 10b. In another embodiment, the top annular connection part Cᵤₚₚₑᵣ of the annular partition wall 15 can be connected with the lower surface of the bottom disk-shaped member 10b or the lower surface of the top disk-shaped member 10a. In this case, vertically under the top annular connection part Cᵤₚₚₑᵣ is assumed to represent vertically under the inside circumferential end of the top annular connection part Cᵤₚₚₑᵣ. The radius RCᵤₚₚₑᵣ of the top annular connection part Cᵤₚₚₑᵣ is “RCᵤₚₚₑᵣ=d3/2”, and the radius R of the setting position W of the work to be polished is “R=d4/2”, where d3 represents the opening inside diameter of the top annular connection part Cᵤₚₚₑᵣ, and d4 represents the outside diameter of the setting position W of the work to be polished. The outside diameter of the setting position (circular region) W of the work to be polished is the same value as that of the diameter of the work to be polished (circular shape in a plan view). Therefore, the radius R of the setting position W of the work to be polished is the same value as that of the radius Rw of the work to be polished. With the above polishing head, the radius RCᵤₚₚₑᵣ of the top annular connection part Cᵤₚₚₑᵣ is 33% or more and 90% or less with the radius R of the setting position W of the work to be polished assumed as 100%. As a result of the extensive study by the present inventors, it has been newly proved that this contributes to the suppression of the in-plane fluctuations in polishing amount at the surface to be polished of the work and the enhancement of the in-plane uniformity of the polishing amount. The diameter of the work to be polished can be, for example, 50 mm to 450 mm. For example, when the diameter of the work to be polished is 300 mm, the radius RCᵤₚₚₑᵣ of the top annular connection part Cᵤₚₚₑᵣ is preferably 50 mm or more and 135 mm or less.

When the shape of the surface to be polished of the work to be polished is a concave shape, and the inflection position determined by first-order differentiating the cross-sectional shape profile of the surface to be polished is the position at a distance of X from the center of the surface to be polished toward the outside, the radius RCᵤₚₚₑᵣ of the top annular connection part Cᵤₚₚₑᵣ preferably falls within the following range with respect to the radius R of the setting position W of the work to be polished. The cross-sectional shape profile of the surface to be polished can be determined by a known cross-sectional shape measuring device.
(1) When X is more than 66% with respect to the radius Rw of the work to be polished, the radius RCᵤₚₚₑᵣ of the top annular connection part Cᵤₚₚₑᵣ is preferably 40% or more and 90% or less, more preferably 60% or more and 90% or less, further preferably 70% or more and 90% or less, and still further preferably 80% or more and 90% or less with the radius R of the setting position W of the work to be polished assumed as 100%.
(2) When X is 66% or less with respect to the radius Rw of the work to be polished, the radius RCᵤₚₚₑᵣ of the top annular connection part Cᵤₚₚₑᵣ is preferably 33% or more and 80% or less, more preferably 33% or more and 70% or less, further preferably 33% or more and 60% or less, still further preferably 33% or more and 50% or less, and still furthermore preferably 33% or more and 40% or less with the radius R of the setting position W of the work to be polished assumed as 100%.

As for the annular partition wall, the cross-sectional shape of the annular partition wall preferably at least partially includes the side surface shape selected from the group consisting of an inclined shape and a horizontal shape, and vertically under at least a part of such a side surface shape, a region including the inside circumferential end of the second annular member and the outside circumferential end of the setting position of the work to be polished is more preferably situated. Having such a configuration can lead to the following: upon introducing a gas into the outside space at the time of polishing, at least a part of the inner wall surface of the annular partition wall comes in contact with the upper surface of the membrane. This can contribute to facilitating the following: by changing the amount of the gas to be introduced into the outside space, the polishing amount in the plane (especially, the outer circumferential region) of the work to be polished is controlled. At the time of polishing, normally, a gas is introduced into both of the outside space and the inside space. A polishing head can have a configuration such that when a gas is introduced into the outside space at the time of polishing, at least a part of the inner wall surface of the annular partition wall comes in contact with the upper surface of the membrane. This can be confirmed by, for example, the following: when a gas is introduced into only the outside space without introducing a gas into the inside space, the upper surface of the membrane and at least a part of the inner wall surface of the partition wall come in contact with each other. FIG. 4 is an explanatory view of the inner wall surface of the annular partition wall and the upper surface of the membrane. In FIG. 4, a reference numeral sign 15Aᵢₙₙₑᵣ represents the inner wall surface of the annular partition wall 15A, and a reference numeral sign 13ᵤₚₚₑᵣ represents the upper surface of the membrane 13.

As the specific examples of the cross-sectional shape, in the example shown in FIG. 1, the cross-sectional shape of the annular partition wall 15A is configured such that horizontal shapes are included at the top and the bottom thereof, and such that an inclined shape continues in a bottom horizontal shape. In the example shown in FIG. 5, the cross-sectional shape of the annular partition wall 15B is an inclined shape. In the example shown in FIG. 6, the cross-sectional shape of the annular partition wall 15C includes a horizontal shape. In the example shown in FIG. 7, the cross-sectional shape of the annular partition wall 15D is configured such that an inclined shape continues in a horizontal shape. For example, in the example shown in FIG. 1, by introducing a gas into the outside space 16b at the time of polishing, it is possible to bring a part or the whole of the inner wall surface of the portion in a bottom horizontal shape in a cross-sectional shape into contact with the upper surface of the membrane 13. In the example shown in FIG. 5, by introducing a gas into the outside space 16b at the time of polishing, it is possible to bring a part of, or the whole of the inner wall surface of the annular partition wall 15B in an inclined shape in a cross-sectional shape into contact with the upper surface of the membrane 13. In the example shown in FIG. 6, by introducing a gas into the outside space 16b at the time of polishing, it is possible to bring a part of, or the whole of the inner wall surface of the portion in a horizontal shape in a cross-sectional shape into contact with the upper surface of the membrane 13. In the example shown in FIG. 7, by introducing a gas into the outside space 16b at the time of polishing, it is possible to bring a part of, or the whole of the inner wall surface of the portion in a horizontal shape in a cross-sectional shape into contact with the upper surface of the membrane 13.

### [Polishing Device and Method of Manufacturing Semiconductor Wafer]

One aspect of the present invention relates to a polishing device having the above polishing head, a polishing pad, and a surface plate which supports the polishing pad.

Further, another aspect of the present invention relates to a method of manufacturing a semiconductor wafer, including polishing the surface of a semiconductor wafer to be polished by the above polishing device to form a polished surface.

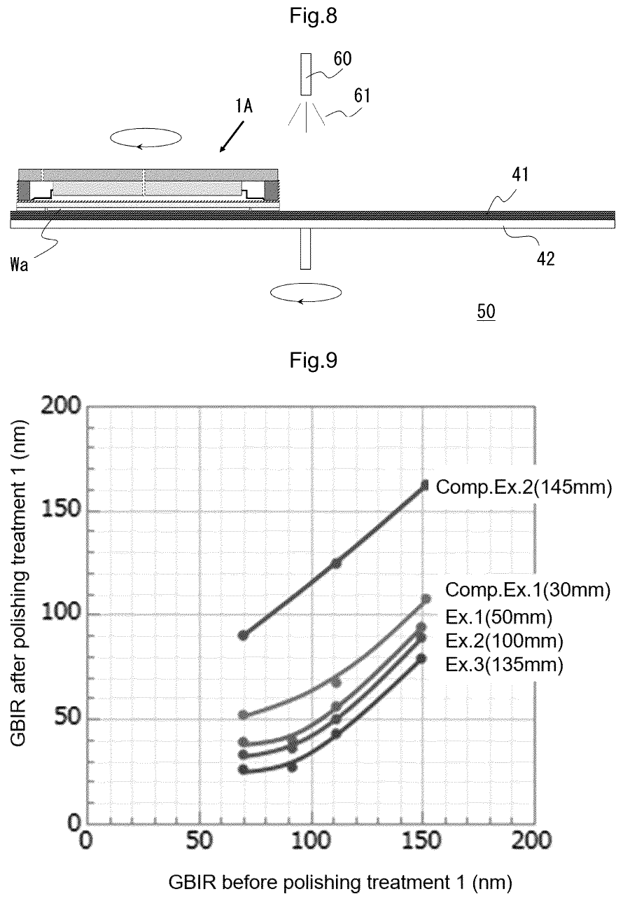

FIG. 8 is a schematic cross-sectional view showing one example of a polishing device in accordance with one aspect of the present invention. A polishing device 50 shown in FIG. 8 includes the polishing head 1A shown in FIG. 1. As with FIG. 1, or the like, the head main body of the polishing head is not shown. The polishing device 50 is a one-side polishing device of a rubber chuck system, whereby while rotating the polishing head 1A and the surface plate 42 by a rotating mechanism (not shown), respectively, the surface to be polished of a work to be polished Wa set at the setting position W of the polishing head 1A is brought into sliding contact with a polishing pad 41 bonded onto the surface plate 42. An abrasive 61 discharged from an abrasive supply mechanism 60 is supplied to between the lower surface of the work Wa that is the surface to be polished of the work Wa, and the polishing pad 41. Thus, the surface to be polished of the work Wa is polished. As the abrasive, a polishing slurry commonly used for CMP (Chemical Mechanical Polishing) can be used. The above polishing device can have the same configuration as that of a normal one-side polishing device except for including the polishing head in accordance with one aspect of the present invention. Further, to the above method of manufacturing a semiconductor wafer, a known technology regarding the method of manufacturing a semiconductor wafer having a polished surface is applicable except for including polishing the surface of a semiconductor wafer to be polished using the polishing device in accordance with one aspect of the present invention to form a polished surface. The wafer to be polished can be, for example, a silicon wafer (preferably, a single crystal silicon wafer). For example, a silicon wafer can be manufactured in the following manner. A single crystal silicon ingot is cut, resulting in a block. The single crystal silicon ingot can be grown by a known method such as the CZ method (Czochralski method) or the FZ method (Floating Zone method). The resulting block is sliced, resulting in a wafer. The wafer is subjected to various processings. As a result, a silicon wafer can be manufactured. As the processings, mention may be made of chamfering processing, flattening processing (lapping, grinding, or polishing), and the like. The above polishing device can be preferably used for, for example, the finish polishing step of the final step of wafer processing.

### EXAMPLES

Below, the present invention will be described by way of Examples. However, the present invention is not limited to the embodiments shown in Examples. The polishing pressure Pe described below is the pressure to be applied downward from the outer circumferential region of the membrane 13 due to swelling of the outer circumferential region of the membrane 13 caused by introduction of a gas from the gas introduction path 17b into the outside space 16b. The polishing pressure Pc is the pressure to be applied downward from the central part of the membrane 13 due to swelling of the central part of the membrane 13 caused by introduction of a gas from the gas introduction path 17a into the inside space 16a. The polishing pressures Pe and Pc are experimental values. The shape of the surface to be polished of the following silicon wafer is a concave shape.

### [Polishing Head]

The polishing head of Example 1 (the two-zone membrane head of the rubber chuck system) is a polishing head with the configuration shown in FIG. 1. The inside diameter d1 of the bottom annular connection part of the annular partition wall is 320 mm, the inside diameter d2 of the second annular member is 301 mm, and the opening inside diameter d3 of the top annular connection part of the annular partition wall is 100 mm (therefore, the radius RCᵤₚₚₑᵣ of the top annular connection part Cᵤₚₚₑᵣ is 50 mm).

A polishing head of Example 2 has the same configuration as that of the polishing head of Example 1, except that the radius RCᵤₚₚₑᵣ of the top annular connection part Cᵤₚₚₑᵣ of the annular partition wall is 100 mm.

A polishing head of Example 3 has the same configuration as that of the polishing head of Example 1, except that the radius RCᵤₚₚₑᵣ of the top annular connection part Cᵤₚₚₑᵣ of the annular partition wall is 135 mm.

A polishing head of Comparative Example 1 has the same configuration as that of the polishing head of Example 1, except that the radius RCᵤₚₚₑᵣ of the top annular connection part Cᵤₚₚₑᵣ of the annular partition wall is 30 mm.

A polishing head of Comparative Example 2 has the same configuration as that of the polishing head of Example 1, except that the radius RCᵤₚₚₑᵣ of the top annular connection part Cᵤₚₚₑᵣ of the annular partition wall is 145 mm.

### [Polishing Treatment 1 of Silicon Wafer]

With a polishing treatment 1, a plurality of silicon wafers (300 mm in diameter) cut out from a single crystal silicon ingot, which were already subjected to various processing treatments, were subjected to a one-side polishing treatment using each polishing head of Examples and Comparative Examples as the finish polishing steps of respective final steps. The inflection position determined by first-order differentiating the cross-sectional shape profile of each surface to be polished of the plurality of silicon wafers was the position more than 100 mm outward from the center of the surface to be polished of the silicon wafer toward the outside. As for the silicon wafer to be polished, GBIR was measured before the polishing treatment. GBIR (Global Backside Ideal Range) is the difference between the maximum value and the minimum value of the thickness upon adsorbing and fixing the wafer (the distance from the back surface reference plane). It can be said as follows: with a lower value of GBIR after the polishing treatment, the in-plane fluctuations in the polishing amount are smaller at the surface to be polished of the work, and the in-plane uniformity of the polishing amount is higher.

As the polishing device of the polishing treatment 1, a polishing device with the configuration shown in FIG. 8 including each polishing head of Examples and Comparative Examples was prepared. With the polishing device, under the following polishing conditions, the one-side polishing treatment of the silicon wafer was performed. The GBIR of each silicon wafer after the polishing treatment was measured.

Pc=10 kPa

Pe=12 kPa

### [Polishing Treatment 2 of Silicon Wafer]

With a polishing treatment 2, a plurality of silicon wafers (300 mm in diameter) cut out from a single crystal silicon ingot, which were already subjected to various processing treatments, were subjected to a one-side polishing treatment using each polishing head of Examples and Comparative Examples as the finish polishing steps of respective final steps. The inflection position determined by first-order differentiating the cross-sectional shape profile of each surface to be polished of the plurality of silicon wafers was the position more than 100 mm inward from the center of the surface to be polished of the silicon wafer toward the outside. As for the silicon wafer to be polished, the GBIR was measured before the polishing treatment.

As the polishing device of the polishing treatment 2, a polishing device with the configuration shown in FIG. 8 including each polishing head of Examples and Comparative Examples was prepared. With the polishing device, under the following polishing conditions, the one-side polishing treatment of the silicon wafer was performed. The GBIR of each silicon wafer after the polishing treatment was measured.

Pc=10 kPa

Pe=12 kPa

FIG. 9 is a graph plotting the GBIR values before and after the polishing treatment for the silicon wafer subjected to the polishing treatment 1 using each polishing head of Examples and Comparative Examples.

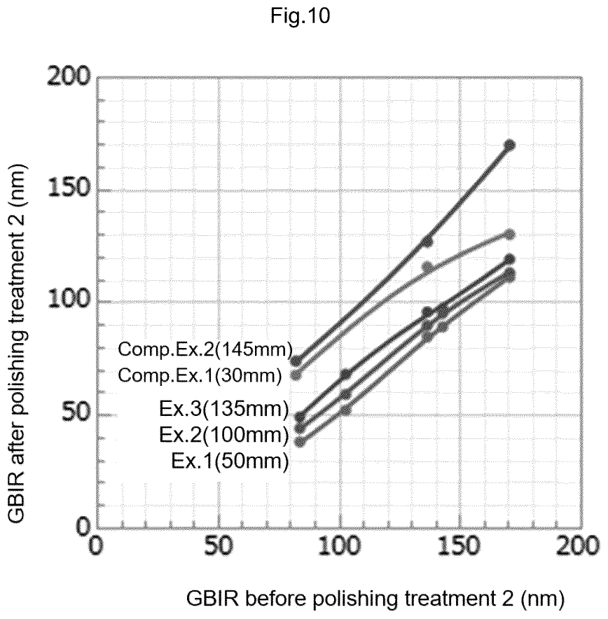

FIG. 10 is a graph plotting the GBIR values before and after the polishing treatment for the silicon wafer subjected to the polishing treatment 2 using each polishing head of Examples and Comparative Examples.

For each polishing head of Examples 1 to 3, Comparative Example 1, and Comparative Example 2, the radius RCᵤₚₚₑᵣ of the top annular connection part Cᵤₚₚₑᵣ IS Example 1: 33%, Example 2: 67%, Example 3: 90%, Comparative Example 1: 20%, and Comparative Example 2: 97% with the radius R of the setting position W of the work to be polished (the radius Rw of the silicon wafer to be polished) assumed as 100%. From the graph shown in FIG. 9 and the graph shown in FIG. 10, it can be confirmed that the value of GBIR is smaller, that is, the in-plane uniformity of the polishing amount is higher when the polishing treatment is performed using each polishing head of Examples 1 to 3 as compared with the case where the polishing treatment is performed using each polishing head of Comparative Example 1 or Comparative Example 2. Further, from the graph shown in FIG. 9, it can be confirmed that, with the polishing treatment 1, the in-plane uniformity of the polishing amount is higher with a larger value of radius RCᵤₚₚₑᵣ of the top annular connection part Cᵤₚₚₑᵣ among Examples 1 to 3. On the other hand, from the graph shown in FIG. 10, it can be confirmed that, with the polishing treatment 2, the in-plane uniformity of the polishing amount is higher with a smaller value of radius RCᵤₚₚₑᵣ of the top annular connection part Cᵤₚₚₑᵣ among Examples 1 to 3.

One aspect of the present invention is useful in the technical field of a semiconductor wafer such as a silicon wafer.

What is claimed is:

1. A polishing head,
which comprises:
a first annular member,
a closing member which closes an upper surface side opening of an opening of the first annular member,
a membrane which closes a lower surface side opening of an opening of the first annular member, and
a second annular member situated under the membrane, and having an opening which holds a work to be polished,
wherein, with a direction toward a center of the opening of the first annular member assumed as an inside, and with the other direction assumed as an outside,
a space, which is formed by closing the opening of the first annular member by the closing member and the membrane, is partitioned into an inside space and an outside space by an annular partition wall with a top annular connection part connected to the closing member and with a bottom annular connection part connected to the membrane,
an inside diameter of the bottom annular connection part of the annular partition wall is larger than an inside diameter of the second annular member, and
a radius of the top annular connection part of the annular partition wall is 33% or more and 90% or less with a radius of a setting position of the work to be polished assumed as 100%.

2. The polishing head according to claim 1,
wherein a shape of a surface to be polished of the work to be polished is a concave shape.

3. The polishing head according to claim 1,
Wherein the annular partition wall comprises a side surface shape selected from the group consisting of an inclined shape and a horizontal shape in a cross-sectional shape, and
vertically under at least a part of the side surface shape, a region including an inside circumferential end of the second annular member and an outside circumferential end of the setting position of the work to be polished is situated.

4. The polishing head according to claim 1,
wherein the closing member comprises a top disk-shaped member and a bottom disk-shaped member having a smaller outside diameter than that of the top disk-shaped member, and
in the annular partition wall, the top annular connection part is connected with a side surface of the bottom disk-shaped member.

5. The polishing head according to claim 1,
which further comprises a back pad between the membrane and the second annular member.

6. The polishing head according to claim 1,
which further comprises:
an introduction path which introduces a gas into the inside space; and
an introduction path which introduces a gas into the outside space.

7. The polishing head according to claim 1,
wherein a shape of a surface to be polished of the work to be polished is a concave shape,
the annular partition wall comprises a side surface shape selected from the group consisting of an inclined shape and a horizontal shape in a cross-sectional shape,
vertically under at least a part of the side surface shape, a region including an inside circumferential end of the second annular member and an outside circumferential end of the setting position of the work to be polished is situated,
the closing member comprises a top disk-shaped member and a bottom disk-shaped member having a smaller outside diameter than that of the top disk-shaped member, and
in the annular partition wall, the top annular connection part is connected with a side surface of the bottom disk-shaped member,
the polishing head further comprises a back pad between the membrane and the second annular member, and
the polishing head further comprises:
an introduction path which introduces a gas into the inside space, and
an introduction path which introduces a gas into the outside space.

8. A polishing device, comprising:
the polishing head according to claim 1;
a polishing pad; and
a surface plate which supports the polishing pad.

9. A method of manufacturing a semiconductor wafer,
which comprises polishing a surface of a semiconductor wafer to be polished by the polishing device according to claim 8 to form a polished surface.
